(19) United States
(12) Patent Application Publication
(10) Pub. No.: US 2024/0291475 A1
(43) Pub. Date: Aug. 29, 2024

(54) OUTPUT DRIVER HAVING HIGH VOLTAGE PROTECTION CIRCUIT

(71) Applicant: SK hynix Inc., Gyeonggi-do (KR)

(72) Inventor: Seung Ho LEE, Gyeonggi-do (KR)

(21) Appl. No.: 18/456,529

(22) Filed: Aug. 28, 2023

(30) Foreign Application Priority Data
Feb. 27, 2023 (KR) 10-2023-0025509

(51) Int. Cl. H03K 17/081

(52) U.S. Cl. CPC H03K 17/08104

(57) ABSTRACT

An output driver includes a pull-up driving circuit coupled between a supply voltage terminal and an output pad, and configured to perform a pull-up operation on the output pad, a pull-down driving circuit coupled between the output pad and a ground terminal, and configured to perform a pull-down operation on the output pad, and a high voltage protection circuit including a resistor string and a transistor that are coupled in series between the output pad and the ground terminal.

### CROSS-REFERENCE TO RELATED APPLICATIONS

The present application claims priority under 35 U.S.C. 119 (a) to Korean Patent Application No. 10-2023-0025509, filed on Feb. 27, 2023, which is incorporated herein by reference in its entirety.

### BACKGROUND

### 1. Technical Field

Embodiments of the present disclosure relate to an output driver, and more particularly, to an output driver having a high voltage protection circuit.

### 2. Related Art

A system on chip (SoC) requires a high-speed interface circuit that requires a low supply voltage and a high-speed operation. To this end, a triple gate oxide (TGO) process has been applied using a MOS transistor having a thin gate oxide film for a relatively low core voltage operation and MOS transistors having two different thicknesses of thick gate oxide films for a relatively high output voltage operation. However, with the recent introduction of micro-processing to semiconductor devices used in the system-on-chip (SOC), a dual gate oxide (DGO) process is applied instead of the triple gate oxide process, which is a very complex manufacturing process. That is, as the elements constituting the operating circuit, a MOS transistor having a thin gate oxide film for the core voltage operation and a MOS transistor having a thick gate oxide film for the output voltage operation are used. For example, when a process of 28 nm or less is applied, a MOS transistor having a thin gate oxide film for an operation of 0.9 V and a MOS transistor having a thick gate oxide film for an operation of 1.8 V or 2.5 V (or 3.3 V) are used.

Recently, in order to support all possible interface protocols from a low voltage to a high voltage, in operating an output driver, a low voltage as a core voltage, for example 0.9 V, a medium voltage as a first output voltage, for example 1.8 V, and a high voltage as a second output voltage, for example 3.3 V are all used. In this case, it is necessary to implement a cell transistor of an internal circuit with a MOS transistor for a low voltage operation having a relatively thin gate insulating layer and to implement a medium voltage interface solution and a high voltage interface solution with a MOS transistor for a medium voltage operation having a relatively thick gate insulation layer, by applying the dual gate oxide process. However, when an interface operation for a high voltage is performed with a MOS transistor for the medium voltage operation, an issue may occur due to the reliability of the MOS transistor for the medium voltage operation. In particular, with the supply voltage terminal of the output driver in an OFF state, while the voltage applied to the pads of the output driver changes from low voltage to high voltage or from high voltage to low voltage, the MOS transistors for the medium voltage operation included in the output driver may be damaged due to the high voltage.

### SUMMARY

An output driver according to an embodiment of the present disclosure may include a pull-up driving circuit coupled between a supply voltage terminal and an output pad, and configured to perform a pull-up operation on the output pad, a pull-down driving circuit coupled between the output pad and a ground terminal, and configured to perform a pull-down operation on the output pad, and a high voltage protection circuit including a resistor string and a transistor that are coupled in series between the output pad and the ground terminal.

An output driver according to other embodiment of the present disclosure may include a pull-up driving circuit including a first PMOS transistor and a second PMOS transistor coupled in series between a supply voltage terminal and an output pad, and configured to perform a pull-up operation on the output pad, and a dynamic gate bias circuit coupled between a gate of the second PMOS transistor and the output pad, and configured to dynamically vary a level of a gate of the second PMOS transistor.

### BRIEF DESCRIPTION OF THE DRAWINGS

FIG. 1 is a circuit diagram illustrating an output driver according to an embodiment of the present disclosure.

FIG. 2 is a circuit diagram illustrating a floating well voltage generating circuit included in the output driver of FIG. 1.

FIG. 3 is a block diagram illustrating a control circuit included in the output driver of FIG. 1.

FIG. 4 is a table for describing operations of a voltage selection signal generating circuit and a high voltage detecting circuit included in the control circuit of FIG. 3.

FIG. 5 is a circuit diagram illustrating the high voltage detecting circuit included in the control circuit of FIG. 3.

FIG. 6 is a circuit diagram illustrating an output driver according to an embodiment of the present disclosure.

FIG. 7 is a circuit diagram illustrating an output driver according to an embodiment of the present disclosure.

FIG. 8 is a circuit diagram illustrating an output driver according to an embodiment of the present disclosure.

### DETAILED DESCRIPTION OF THE EMBODIMENTS

In the description of the embodiments of the present disclosure, descriptions such as “first” and “second” are for distinguishing elements, and are not used to limit the elements themselves or to mean a specific order. The description that one component is “connected” or “coupled” to another component may mean electrically or mechanically directly connected or connected to another component. Alternatively, other separate components may be interposed in the middle to form a connection relationship. The term “predetermined” means that the value of a parameter is predetermined when using that parameter in a process or algorithm. The value of the parameter may be set when a process or algorithm starts or may be set during a period during which a process or algorithm is performed, depending on embodiments.

“Logic high level” and “logic low level” are used to describe logic levels of signals. A signal having a “logic high level” is distinguished from a signal having a “logic low level”. For example, when a signal having a first voltage corresponds to a “logic high level”, a signal having a second voltage may correspond to a “logic low level”. According to an embodiment, the “logic high level” may be set to a higher voltage than the “logic low level”. Moreover, the logic levels of the signals may be set to other logic levels or opposite logic levels according to embodiments. For example, a signal having a logic high level may be set to have a logic low level according to embodiments, and a signal having a logic low level may be set to have a logic high level according to embodiments.

Various embodiments of the present disclosure will be described hereinafter in more detail with reference to the accompanying drawings. In the following various embodiments, the terms “medium voltage” and “high voltage” refer to voltages of relatively different magnitudes. As an example, the description will be made based on that the medium voltage is approximately 1.8 V and the high voltage is approximately 3.3 V.

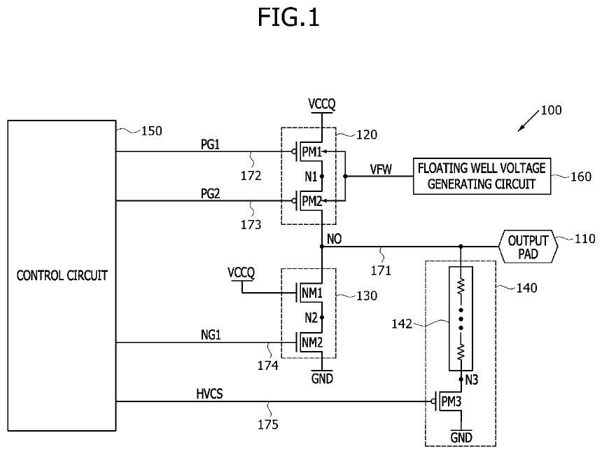

FIG. 1 is a circuit diagram illustrating an output driver 100 according to an embodiment of the present disclosure. Referring to FIG. 1, the output driver 100 may include a pull-up driving circuit 120, a pull-down driving circuit 130, a high voltage protection circuit 140, and a floating well voltage generating circuit 160, and may further include a control circuit 150.

An output pad 110 may be coupled to an output node NO through an output line 171. The pull-up driving circuit 120 may be coupled between a supply voltage terminal VCCQ and the output node NO. The pull-up driving circuit 120 may perform a pull-up operation on the output pad 110 according to an output signal output from an internal circuit (not shown). By the pull-up operation of the pull-up driving circuit 120, a supply voltage may be output to the output pad 110 through the output line 171. The pull-up operation of the pull-up driving circuit 120 may be controlled by a first gate signal PG1 and a second gate signal PG2 provided from the control circuit 150. The pull-up driving circuit 120 may receive a floating well voltage VFW generated from the floating well voltage generating circuit 160. The pull-down driving circuit 130 may be coupled between the output node NO and a ground terminal GND. The pull-down driving circuit 130 may perform a pull-down operation on the output pad 110 according to the output signal output from the internal circuit (not shown). By the pull-down operation of the pull-down driving circuit 130, a ground voltage may be output to the output pad 110 through the output line 171. The pull-down operation of the pull-down driving circuit 130 may be controlled by the supply voltage and a third gate signal NG1.

The high voltage protection circuit 140 may be coupled between the output line 171 and the ground terminal GND. The high voltage protection circuit 140 may block coupling between the output line 171 and the ground terminal GND when a pad voltage applied to the output pad 110 is equal to or less than the supply voltage applied to the supply voltage terminal VCCQ. On the other hand, when the pad voltage applied to the output pad 110 is greater than the supply voltage applied to the supply voltage terminal VCCQ, the high voltage protection circuit 140 may generate a drop of the pad voltage between the output line 171 and the ground terminal GND.

The control circuit 150 may generate control signals PG1, PG2, NG1, and HVCS for controlling the pull-up driving circuit 120, the pull-down driving circuit 130, and the high voltage protection circuit 140. The control circuit 150 may generate the first gate signal PG1 and the second gate signal PG2 to transmit the first and second gate signals PG1 and PG2 to the pull-up driving circuit 120. The control circuit 150 may generate the third gate signal NG1 to transmit the third gate signal NG1 to the pull-down driving circuit 130. The control circuit 150 may generate the high voltage protection circuit control signal HVCS to transmit the high voltage protection circuit control signal HVCS to the high voltage protection circuit 140. Although omitted from FIG. 1, in order to generate the high voltage protection circuit control signal HVCS, the control circuit 150 may receive the supply voltage through the supply voltage terminal VCCQ, and receive the floating well voltage VFW from the floating well voltage generating circuit 160.

The floating well voltage generating circuit 160 may generate the floating well voltage VFW that varies according to a voltage of the output pad 110. The floating well voltage generating circuit 160 may provide the floating well voltage VFW to the pull-up driving circuit 120 and the control circuit 150. Although omitted in the drawing, in order to generate the floating well voltage VFW, the floating well voltage generating circuit 160 may receive the supply voltage through the supply voltage terminal VCCQ and receive the pad voltage through the output pad 110.

More specifically, the pull-up driving circuit 120 may include a first P-channel type MOS (hereinafter, referred to as “PMOS”) transistor PM1 and a second PMOS transistor PM2. Both the first PMOS transistor PM1 and the second PMOS transistor PM2 may be configured with transistors for an intermediate voltage operation, which operate with a supply voltage of a medium voltage (i.e., 1.8 V). The first PMOS transistor PM1 may be coupled between the supply voltage terminal VCCQ and a first node N1. The second PMOS transistor PM2 may be coupled between the first node N1 and the output node N0. A gate of the first PMOS transistor PM1 may be coupled to a first gate signal input line 172. Accordingly, the first gate signal PG1 output from the control circuit 140 may be applied to the gate of the first PMOS transistor PM1 through the first gate signal input line 172. A source and a drain of the first PMOS transistor PM1 may be connected to the supply voltage terminal VCCQ and the first node N1, respectively. A gate of the second PMOS transistor PM2 may be coupled to a second gate signal input line 173. Accordingly, the second gate signal PG2 may be applied to the gate of the second PMOS transistor PM2 through the second gate signal input line 173. A source and a drain of the second PMOS transistor PM2 may be coupled to the first node N1 and the output node N0, respectively. An N-type well region of the first PMOS transistor PM1 and an N-type well region of the second PMOS transistor PM2 may receive the floating well voltage VFW generated from the floating well voltage generating circuit 160 in common.

The pull-down driving circuit 130 may include a first N-channel type MOS (hereinafter, referred to as “NMOS”) transistor NM1 and a second NMOS transistor NM2. Both the first NMOS transistor NM1 and the second NMOS transistor NM2 may be configured with transistors for a medium voltage operation, which operate with a supply voltage of a medium voltage (i.e., 1.8 V). The first NMOS transistor NM1 may be coupled between the output node N0 and a second node N2. The second NMOS transistor NM2 may be coupled between the second node N2 and the ground terminal GND. A gate of the first NMOS transistor NM1 may be coupled to the supply voltage terminal VCCQ. A drain and a source of the first NMOS transistor NM1 may be coupled to the output node NO and the second node N2, respectively. A gate of the second NMOS transistor NM2 may be coupled to a third gate signal input line 174. Accordingly, the third gate signal NG1 output from the control circuit 150 may be applied to the gate of the second NMOS transistor NM2 through the third gate signal input line 174. A drain and a source of the second NMOS transistor NM2 may be coupled to the second node N2 and the ground terminal GND, respectively.

The high voltage protection circuit 140 may include a resistor string 142 and a third PMOS transistor PM3. The resistor string 142 may be configured with a plurality of resistors connected in series. The resister string 142 may be coupled between the output line 171 and a third node N3. The third PMOS transistor PM3 may be coupled between the third node N3 and the ground terminal GND. A gate of the third PMOS transistor PM3 may be coupled to a high voltage protection circuit control signal input line 175. Accordingly, the high voltage protection circuit control signal HVCS output from the control circuit 150 may be applied to the gate of the third PMOS transistor PM3 along the high voltage protection circuit control signal input line 175. A source and a drain of the third PMOS transistor PM3 may be coupled to the third node N3 and the ground terminal GND, respectively.

In a state in which the supply voltage terminal VCCQ is in an ON state, that is, in a state in which a supply voltage of 1.8 V is provided through the supply voltage terminal VCCQ, when a pad voltage greater than the supply voltage, for example, a pad voltage of 3.3 V is applied to the output pad 110, the control circuit 150 may output the high voltage protection circuit control signal HVCS of a ground voltage 0V. The high voltage protection circuit control signal HVCS of the ground voltage 0 V may be applied to the gate of the third PMOS transistor PM3 of the high voltage protection circuit 140, and accordingly, the third PMOS transistor PM3 may be turned-on. Similarly, in a state in which the supply voltage terminal VCCQ is in an OFF state, that is, in a state in which a supply voltage of 1.8 V is not provided through the supply voltage terminal VCCQ, when a pad voltage greater than the supply voltage, for example, a pad voltage of 3.3 V is applied to the output pad 110, the control circuit 150 may output the high voltage protection circuit control signal HVCS of the ground voltage 0 V. The high voltage protection circuit control signal HVCS of the ground voltage 0 V may be applied to the gate of the third PMOS transistor PM3, and accordingly, the third PMOS transistor PM3 may be turned-on.

As the third PMOS transistor PM3 is turned-on, the output line 171 may be branched into a path toward the output node NO and a path where the register string 142 is disposed. Accordingly, a voltage drop may occur in proportion to a resistance value of the resistor string 142, and as a result, the voltage applied to the output node NO may have a smaller magnitude than the high voltage applied to the output pad 110. Accordingly, reliability of the MOS transistors PM1, PM2, NM1, and NM2 for a medium voltage operation, constituting the output driver 100 may be maintained. Furthermore, the floating well voltage generating circuit 160 may output a floating well voltage VFW of 3.3 V, which is the pad voltage, to bias the N-type well regions of the first PMOS transistor PM1 and the second PMOS transistor PM2 constituting the pull-up driving circuit 120 to a voltage of 3.3 V. Accordingly, a phenomenon in which a current flows to the supply voltage terminal VCCQ as the output node NO due to a parasitic diode may be suppressed.

On the other hand, when a voltage equal to or less than the supply voltage applied to the supply voltage terminal VCCQ is applied to the output pad 110 while the supply voltage terminal VCCQ is in an ON state or in an OFF state, the control circuit 150 may output the high voltage protection circuit control signal HVCS of an intermediate voltage, for example, 1.8 V. The high voltage protection circuit control signal HVCS of 1.8 V may be applied to the gate of the third PMOS transistor PM3 of the high voltage protection circuit 140, and accordingly, the third PMOS transistor PM3 may be turned-off. As the third PMOS transistor PM3 is turned-off, the high voltage protection circuit 140 coupled between the output line 171 and the ground terminal GND may be opened. As a result, the voltage applied to the output node NO may be still applied to the output pad 110 without voltage drop.

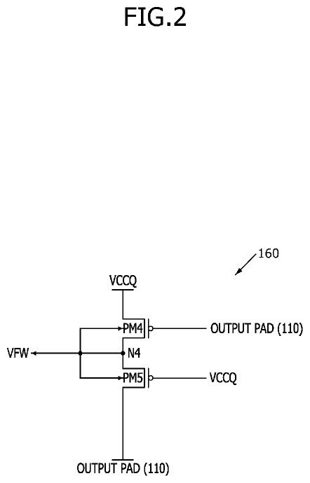

FIG. 2 is a circuit diagram illustrating the floating well voltage generating circuit 160 included in the output driver 100 of FIG. 1. Referring to FIG. 2, the floating well voltage generating circuit 160 may include a fourth PMOS transistor PM4 and a fifth PMOS transistor PM5 coupled between the supply voltage terminal VCCQ and the output pad 110. In an embodiment, each of the fourth PMOS transistor PM4 and the fifth PMOS transistor PM5 may be configured with a PMOS transistor for a medium voltage operation, for example, a PMOS transistor operating with a supply voltage of 1.8 V. A gate of the fourth PMOS transistor PM4 may be coupled to the output pad 110. A source and a drain of the fourth PMOS transistor PM4 may be coupled to the supply voltage terminal VCCQ and a fourth node N4, respectively. A gate of the fifth PMOS transistor PM5 may be coupled to the supply voltage terminal VCCQ. A source and a drain of the fifth PMOS transistor PM5 may be coupled to the fourth node N4 and the output pad 110, respectively. In the floating well voltage generating circuit 160, the fourth node N4 may serve as an output node that outputs the floating well voltage VFW, which is an output signal. The N-type well region of the fourth PMOS transistor PM4 and the N-type well region of the fifth PMOS transistor PM5 may receive the floating well voltage VFW generated from the fourth node N4.

When the pad voltage in the output pad 110 is equal to the medium voltage, that is, 1.8 V, both the fourth PMOS transistor PM4 and the fifth PMOS transistor PM5 may be turned-off. When the pad voltage at the output pad 110 is greater than the medium voltage, that is, 1.8 V, for example, the pad voltage is 3.3 V, the fourth PMOS transistor PM4 may be turned-off, and the fifth PMOS transistor PM5 may be turned-on. In this case, the voltage at the fourth node N4 may be the same as the pad voltage (i.e., 3.3 V), and accordingly, the floating well voltage VFW having the same magnitude as the pad voltage (i.e., 3.3 V) may be output from the fourth node N4.

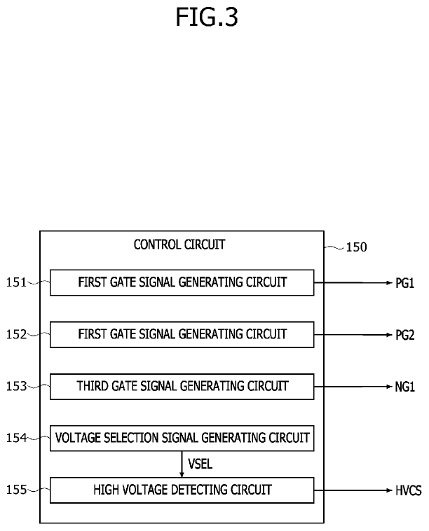

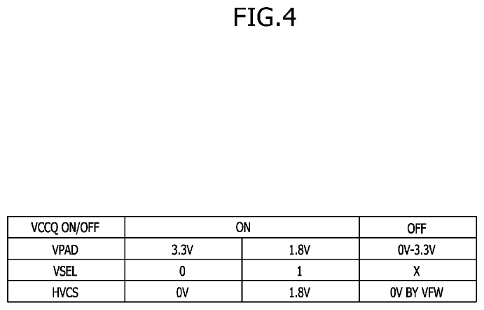

FIG. 3 is a block diagram illustrating the control circuit 150 included in the output driver 100 of FIG. 1. FIG. 4 is a table for describing operations of a voltage selection signal generating circuit 154 and a high voltage detecting circuit 155 included in the control circuit 150 of FIG. 3.

First, referring to FIG. 3, the control circuit 150 may include a first gate signal generating circuit 151, a second gate signal generating circuit 152, a third gate signal generating circuit 153, the voltage selection signal generating circuit 154, and the high voltage detecting circuit 155. The first gate signal generating circuit 151 may generate the first gate signal PG1 to transmit the first gate signal PG1 to the gate of the first PMOS transistor PM1 constituting the pull-up driving circuit (120 of FIG. 1). The second gate signal generating circuit 152 may generate the second gate signal PG2 to transmit the second gate signal PG2 to the gate of the second PMOS transistor PM2 constituting the pull-up driving circuit (120 of FIG. 1). The third gate signal generating circuit 153 may generate the third gate signal NG1 to transmit the third gate signal NG1 to the gate of the second NMOS transistor NM2 constituting the pull-down driving circuit (130 of FIG. 1).

The voltage selection signal generating circuit 154 may generate a voltage selection signal VSEL, based on a state of the supply voltage terminal VCCQ and a magnitude of a pad voltage VPAD at the output pad (110 of FIG. 1). The voltage selection signal generating circuit 154 may transmit the voltage selection signal VSEL to the high voltage detecting circuit 155. The high voltage detecting circuit 155 may generate the high voltage protection circuit control signal HVCS, based on the voltage selection signal VSEL transmitted from the voltage selection signal generating circuit 154.

As shown in FIG. 4, the voltage selection signal generating circuit 154 may output the voltage selection signal VSEL having a binary value of “0” (or a logic “low” signal) or a binary value of “1” (or a logic “high” signal). Under specific conditions, an output line of the voltage selection signal generating circuit 154 may become floating, as indicated by an “X” in the FIG. 4. In this case, the voltage selection signal VSEL are not output from the voltage selection signal generating circuit 154. Specifically, in a case in which the supply voltage terminal VCCQ is in an ON state, that is, in a case in which a supply voltage of 1.8 V is normally supplied through the supply voltage terminal VCCQ, when the pad voltage VPAD is 1.8 V, the voltage selection signal generating circuit 154 may generate the voltage selection signal VSEL of “1”. Under the same condition, when the pad voltage VPAD is 3.3 V, the voltage selection signal generating circuit 154 may generate the voltage selection signal VSEL of “0”. On the other hand, in a case in which the supply voltage terminal VCCQ is in an OFF state, that is, in a case in which the supply voltage is not provided through the supply voltage terminal VCCQ, the voltage selection signal generating circuit 154 might not output the voltage selection signal VSEL.

When the voltage selection signal VSEL of “0” is transmitted from the voltage selection signal generating circuit 154, the high voltage detecting circuit 155 may output the high voltage protection circuit control signal HVCS of 0 V. When the voltage selection signal VSEL of “1” is transmitted from the voltage selection signal generating circuit 154, the high voltage detecting circuit 155 may output a high voltage protection circuit control signal HVCS of the same magnitude as the supply voltage, that is, 1.8 V. While the voltage selection signal VSEL is not transmitted from the voltage selection signal generating circuit 154, the high voltage detecting circuit 155 may maintain the high voltage protection circuit control signal HVCS of 0 V by the floating well voltage VFW.

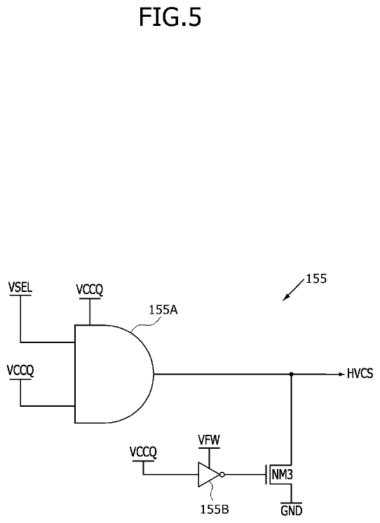

FIG. 5 is a circuit diagram illustrating the high voltage detecting circuit 155 included in the control circuit 150 of FIG. 3.

Referring to FIG. 5, the voltage detecting circuit 155 may include an AND gate 155A, a third NMOS transistor NM3, and an inverter 155B. The AND gate 155A may receive the voltage selection signal VSEL through a first input terminal. A second input terminal of the AND gate 155A may be coupled to the supply voltage terminal VCCQ. Accordingly, when the supply voltage terminal VCCQ is in an ON state, the supply voltage (i.e., 1.8 V) may be applied to the second input terminal of the AND gate 155A. The AND gate 155A may receive an operation voltage from the supply voltage terminal VCCQ. The AND gate 155A may output the high voltage protection circuit control signal HVCS through an output line connected to an output terminal. The third NMOS transistor NM3 may be coupled between the output line connected to the output terminal of the AND gate 155A and the ground terminal GND. A drain of the third NMOS transistor NM3 may be coupled to the output line connected to the output terminal of the AND gate 155A. A source of the third NMOS transistor NM3 may be coupled to the ground terminal GND. A gate of the third NMOS transistor NM3 may be coupled to an output terminal of the inverter 155B. The inverter 155B may include an input terminal and the output terminal. The input terminal of the inverter 155B may be coupled to the supply voltage terminal VCCQ. The output terminal of the inverter 155B may be coupled to the gate of the third NMOS transistor NM3. The inverter 155B may receive an operating voltage from the supply voltage terminal VCCQ.

When the supply voltage terminal VCCQ is in an ON state, the supply voltage of 1.8 V (i.e., a logic value of “1”) may be transmitted to the second input terminal of the AND gate 155A and the input terminal of the inverter 155B. The high voltage protection circuit control signal HVCS output from the AND gate 155A may have the same logic level as the voltage selection signal VSEL. Accordingly, when the voltage selection signal VSEL of “0” is transmitted to the first input terminal of the AND gate 155A, the AND gate 155A may output the high voltage protection circuit control signal HVCS having a magnitude of 0 V corresponding to a logic value of “0” through the output terminal. In this case, as described above with reference to FIG. 1, the third PMOS transistor PM3 of the high voltage protection circuit 140 may be turned-on, and the voltage of the output line 171 may be decreased due to voltage drop by the resistor string 142 of the high voltage protection circuit 140. On the other hand, when the voltage selection signal VSEL of “1” is transmitted to the first input terminal of the AND gate 155A, the AND gate 155A may output the high voltage protection circuit control signal HVCS having a magnitude of 1.8 V corresponding to a logic value of “1” through the output terminal. The inverter 155B may perform an inverting operation on the supply voltage input through the input terminal, that is, 1.8 V. The inverter 155B may provide an inverted supply voltage, that is, 0 V to the gate of the third NMOS transistor NM3 through the output terminal. Accordingly, while the supply voltage terminal VCCQ is in an ON state, the third NMOS transistor NM3 remains turned-off, and as a result, the high voltage protection circuit control signal HVCS output through the output terminal of the AND gate 155A may be output from the high voltage detecting circuit 155 as it is without changing magnitude. In this case, the third PMOS transistor PM3 of the high voltage protection circuit 140 may be turned-off, and a voltage drop by the resistor string 142 of the high voltage protection circuit 140 might not occur.

When the supply voltage terminal VCCQ is in an OFF state, that is, the supply voltage of 1.8 V (i.e., a logic value of “1”) is not applied through the supply voltage terminal VCCQ, as described with reference to FIG. 4, the voltage selection signal VSEL might not be provided to the first input terminal of the AND gate 155A. In this case, the voltage at the output line coupled to the output terminal of the AND gate 155A may be determined by the state of the third NMOS transistor NM3. Because the supply voltage terminal VCCQ is in an OFF state, the inverter 155B may output the floating well voltage VFW through the output terminal. When the pad voltage VDD is 3.3 V, the floating well voltage VFW may have a magnitude of 3.3 V, and in this case, the third NMOS transistor NM3 may be turned-on. Therefore, the voltage of the output line coupled to the output terminal of the AND gate 155A may become the ground voltage, that is, 0 V, and the high voltage detecting circuit 155 may output the high voltage protection circuit control signal HVCS of 0 V. In this case, as described above with reference to FIG. 1, the third PMOS transistor PM3 of the high voltage protection circuit 140 may be turned-on, and the voltage of the output line 171 may be lowered due to the voltage drop by the resistor string 142 of the high voltage protection circuit 140.

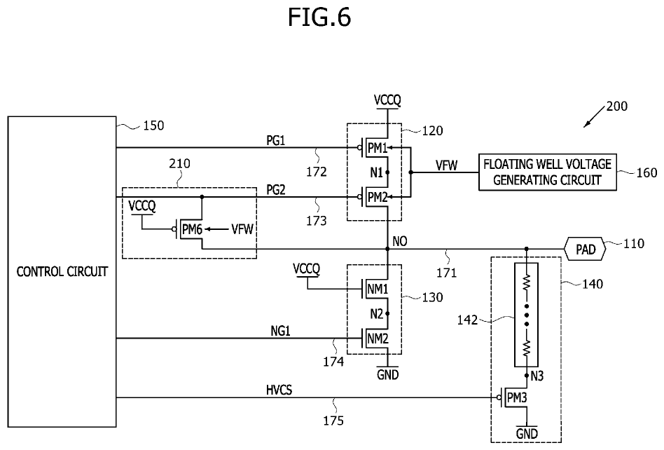

FIG. 6 is a circuit diagram illustrating an output driver 200 according to an embodiment of the present disclosure. In FIG. 6, the same reference numerals as those in FIG. 1 denote the same components, and duplicate descriptions will be omitted below. The output driver 200 is different from the output driver 100 described with reference to FIG. 1, in that the output driver 200 further includes a dynamic gate bias circuit 210.

Referring to FIG. 6, the dynamic gate bias circuit 210 may include a sixth PMOS transistor PM6 coupled between a second gate signal input line 173 and an output node NO. A gate of the sixth PMOS transistor PM6 may be coupled to a supply voltage terminal VCCQ. A source and a drain of the sixth PMOS transistor PM6 may be coupled to the second gate signal input line 173 and the output node NO, respectively. A floating well voltage VFW generated from a floating well voltage generating circuit 160 may be applied to an N-type well region of the sixth PMOS transistor PM6. When a pad voltage of 3.3 V is applied to an output pad 110, the sixth PMOS transistor PM6 may be turned-on, and accordingly, a gate and a drain of a second PMOS transistor PM2 constituting a pull-up driving circuit 120 may be connected to each other. In this state, as the pad voltage of 3.3 V is applied to the N-type well region of the second PMOS transistor PM2 instead of a supply voltage of 1.8 V, a leakage current flowing from the output pad 110 to the supply voltage terminal VCCQ may be blocked.

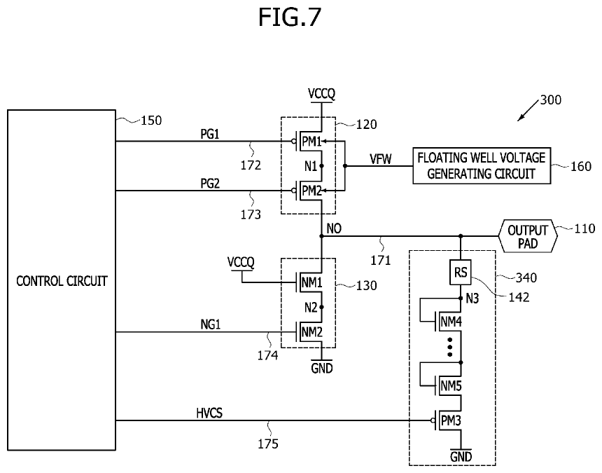

FIG. 7 is a circuit diagram illustrating an output driver 300 according to an embodiment of the present disclosure. In FIG. 7, the same reference numerals as those in FIG. 1 denote the same components, and duplicate descriptions will be omitted below. The output driver 300 is different from the output driver 100 described with reference to FIG. 1, in that a high voltage protection circuit 340 further includes a plurality of diode-connected NMOS transistors NM4 and NM5.

Referring to FIG. 7, the high voltage protection circuit 340 may include the plurality of diode-connected NMOS transistors NM4 and NM5 coupled between a resistor string (RS) 142 and a third PMOS transistor PM3. For example, the first diode-connected NMOS transistor NM4 may be connected in series to the resistor string 142. A gate and a drain (i.e., a third node N3 in FIG. 7) of the first diode-connected NMOS transistor NM4 may be connected to each other. Accordingly, the gate and drain of the first diode-connected NMOS transistor NM4 may be connected in common to an end of the resistor string 142. A source of the first diode-connected NMOS transistor NM4 may be coupled to a drain of another diode-connected NMOS transistor that is connected in series to the first diode-connected NMOS transistor NM4. Likewise, a gate and a drain of the second diode-connected NMOS transistor NM5 may be connected to each other. The gate and drain of the second diode-connected NMOS transistor NM5 may be connected in common to a source of another diode-connected NMOS transistor that is connected in series to the second diode-connected NMOS transistor NM5. A source of the second diode-connected NMOS transistor NM5 may be connected in series to a source of a third PMOS transistor PM3. The plurality of diode-connected NMOS transistors NM4 and NM5 may function like a resistor as they always operate in a saturation region. Accordingly, the number of resistors constituting the resistor string 142 may be reduced, and a circuit area may be reduced.

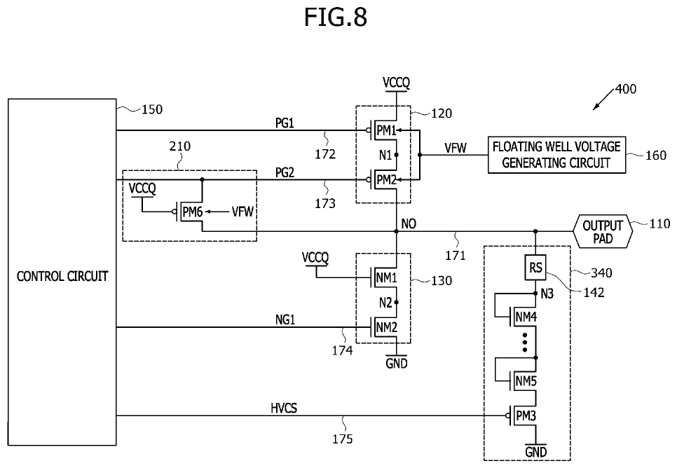

FIG. 8 is a circuit diagram illustrating an output driver 400 according to an embodiment of the present disclosure. In FIG. 8, the same reference numerals as those in FIG. 7 denote the same components, and duplicate descriptions will be omitted below.

Referring to FIG. 8, the output driver 400 is different from the output driver 300 described with reference to FIG. 7, in that the output driver 400 further includes a dynamic gate bias circuit 210. The dynamic gate bias circuit 210 may include a sixth PMOS transistor PM6 coupled between a second gate signal input line 173 and an output node NO. A gate of the sixth PMOS transistor PM6 may be coupled to a supply voltage terminal VCCQ. A source and a drain of the sixth PMOS transistor PM6 may be coupled to the second gate signal input line 173 and the output node NO, respectively. A floating well voltage VFW generated from a floating well voltage generating circuit 160 may be applied to an N-type well region of the sixth PMOS transistor PM6. A description of the operation of the dynamic gate bias circuit 210 may be the same as that described with reference to FIG. 6.

Concepts have been disclosed in conjunction with some embodiments as described above. Those skilled in the art will appreciate that various modifications, additions, and substitutions are possible, without departing from the scope and spirit of the present disclosure. Accordingly, the embodiments disclosed in the present specification should be considered from not a restrictive standpoint but rather from an illustrative standpoint. The scope of the concepts is not limited to the above descriptions but defined by the accompanying claims, and all of distinctive features in the equivalent scope should be construed as being included in the concepts.

It will be evident to a person having ordinary knowledge in the art to which the present disclosure pertains that the present disclosure described above is not limited by the aforementioned embodiments and the accompanying drawings and that the present disclosure may be substituted, modified, and changed in various ways without departing from the technical spirit of the present disclosure.

For example, the locations and types of the logic gates and the transistors illustrated in the aforementioned embodiments have to be differently implemented depending on the polarity of an input signal.

While the present invention has been illustrated and described with respect to specific embodiments, these embodiments are not intended to be restrictive, but rather descriptive. Further, it is noted that the present invention may be achieved in various ways through substitution, change, and modification, as would be understood by those skilled in the art, without departing from the spirit and/or scope of the present invention as defined by the following claims. Furthermore, the embodiments may be combined to form additional embodiments.

What is claimed is:

1. An output driver comprising:
a pull-up driving circuit coupled between a supply voltage terminal and an output pad, and configured to perform a pull-up operation on the output pad;
a pull-down driving circuit coupled between the output pad and a ground terminal, and configured to perform a pull-down operation on the output pad; and
a high voltage protection circuit including a resistor string and a transistor that are coupled in series between the output pad and the ground terminal.

2. The output driver of claim 1, wherein the high voltage protection circuit is configured to:
block coupling between the output pad and the ground terminal when a pad voltage applied to the output pad is equal to or less than a supply voltage applied to the supply voltage terminal; and
generate a drop in the pad voltage between the output pad and the ground terminal when the pad voltage applied to the output pad is greater than the supply voltage applied to the supply voltage terminal.

3. The output driver of claim 1, wherein the high voltage protection circuit further includes a plurality of diode-connected transistors coupled in series between the resistor string and the transistor.

4. The output driver of claim 1, further comprising a control circuit configured to provide gate signals to the pull-up driving circuit and the pull-down driving circuit,
wherein the control circuit includes a voltage selection signal generating circuit configured to output a voltage selection signal having a logic low level or a logic high level according to a magnitude of the pad voltage.

5. The output driver of claim 4, wherein the voltage selection signal generating circuit is configured to:
have an output line in a floating state when the supply voltage terminal is in an OFF state;
output the voltage selection signal having a logic high level when the pad voltage is equal to the supply voltage; and
output the voltage selection signal having a logic low level when the pad voltage is greater than the supply voltage.

6. The output driver of claim 4, wherein the control circuit further includes a high voltage detecting circuit configured to generate a high voltage protection circuit control signal in response to the voltage selection signal from the voltage selection signal generating circuit.

7. The output driver of claim 6, wherein the high voltage detecting circuit is configured to transmit the high voltage protection circuit control signal to a gate of the transistor of the high voltage protection circuit.

8. The output driver of claim 7, wherein the high voltage detecting circuit is configured to:
output a ground voltage as the high voltage protection circuit control signal when the supply voltage terminal is in an OFF state or when the pad voltage is greater than the supply voltage; and
output the supply voltage as the high voltage protection circuit control signal when the pad voltage is equal to the supply voltage.

9. The output driver of claim 6, wherein the high voltage detecting circuit includes:
an AND gate configured to receive the voltage selection signal through a first input terminal, receive the supply voltage through a second input terminal, and output the high voltage protection circuit control signal through an output terminal;
a transistor coupled between the output pad and the ground terminal; and
an inverter configured to invert the supply voltage to generate an inverted supply voltage, and provide an inverted supply voltage to a gate of the transistor.

10. The output driver of claim 9, further comprising a floating well voltage generating circuit coupled between the supply voltage terminal and the output pad, and configured to generate a floating well voltage,
wherein the inverter receives the floating well voltage as a pull-up voltage.

11. The output driver of claim 1, further comprising a floating well voltage generating circuit coupled between the supply voltage terminal and the output pad, and configured to generate a floating well voltage,
wherein the pull-up driving circuit includes a first PMOS transistor and a second PMOS transistor, and
wherein N-type well regions of the first PMOS transistor and the second PMOS transistor receive the floating well voltage in common.

12. The output driver of claim 11, wherein the floating well voltage generating circuit includes:
a fourth PMOS transistor having a gate coupled to the output pad, a source coupled to the supply voltage terminal, and a drain coupled to an output line outputting the floating well voltage; and
a fifth PMOS transistor having a gate coupled to the supply voltage terminal, a source coupled to the output line outputting the floating well voltage, and a drain coupled to the output pad.

13. The output driver of claim 12, wherein N-type well regions of the fourth PMOS transistor and the fifth PMOS transistor receive the floating well voltage in common.

14. The output driver of claim 1, further comprising a dynamic gate bias circuit,
wherein the pull-up driving circuit includes a first PMOS transistor and a second PMOS transistor, and
wherein the dynamic gate bias circuit is coupled between a gate signal input line of the second PMOS transistor and the output pad, and configured to dynamically vary a level of a gate signal of the second PMOS transistor.

15. The output driver of claim 14,
wherein the dynamic gate bias circuit includes a sixth PMOS transistor,
wherein a gate of the sixth PMOS transistor is coupled to the supply voltage terminal, a source of the sixth PMOS transistor is coupled to the second gate signal input line, and a drain of the sixth PMOS transistor is coupled to the output pad.

16. The output driver of claim 15, further comprising a floating well voltage generating circuit coupled between the supply voltage terminal and the output pad to generate a floating well voltage,
wherein an N-type well region of the sixth PMOS transistor receives the floating well voltage.

17. The output driver of claim 1,
wherein the pull-up driving circuit includes:
a first PMOS transistor coupled between the supply voltage terminal and a first node; and
a second PMOS transistor coupled between the first node and the output pad, and
wherein the pull-down driving circuit includes:
a first NMOS transistor coupled between the output pad and a second node; and
a second NMOS transistor coupled between the second node and the ground terminal.

18. An output driver comprising:
a pull-up driving circuit including a first PMOS transistor and a second PMOS transistor coupled in series between a supply voltage terminal and an output pad, and configured to perform a pull-up operation on the output pad; and
a dynamic gate bias circuit coupled between a gate of the second PMOS transistor and the output pad, and configured to dynamically vary a level of a gate of the second PMOS transistor.

19. The output driver of claim 18,
wherein the dynamic gate bias circuit includes a third PMOS transistor,
wherein a gate of the third PMOS transistor is coupled to the supply voltage terminal, a source of the third PMOS transistor is coupled to the gate of the second PMOS transistor, and a drain of the third PMOS transistor is coupled to the output pad.

20. The output driver of claim 19, further comprising a floating well voltage generating circuit coupled between the supply voltage terminal and the output pad to generate a floating well voltage,
wherein an N-type well region of the third PMOS transistor receives the floating well voltage.
